(19) United States
(12) Patent Application Publication
(10) Pub. No.: US 2015/0136204 A1
(43) Pub. Date: May 21, 2015

(54) SOLAR CELL STRUCTURE FOR THERMAL INSULATION AND METHOD FOR MANUFACTURING THE SAME

(71) Applicant: EAGON WINDOWS & DOORS CO., LTD., Incheon (KR)

(72) Inventors: Kye-Yong Yang, Incheon (KR); Jung-Hyuk Ahn, Seoul (KR); Jae-Yong Eom, Incheon (KR); Rho-Ho Park, Seoul (KR)

(73) Assignee: EAGON WINDOWS & DOORS CO., LTD., Incheon (KR)

(21) Appl. No.: 14/166,398

(22) Filed: Jan. 28, 2014

(30) Foreign Application Priority Data
Nov. 20, 2013 (KR) 10-2013-0141118

(51) Int. Cl. H01L 31/048; H01L 31/18

(52) U.S. Cl. CPC H01L 31/0488; H01L 31/18
USPC 136/251; 438/58

(57) ABSTRACT

Disclosed is a solar cell structure for thermal insulation, which includes an intermediate support glass plate, a solar cell structure (A) provided at one side based on the support glass plate, and a vacuum glass panel structure (B) provided at the other side based on the support glass plate.

The solar cell structure for thermal insulation may have an insulation function while generating power by using solar ray, thereby saving the energy consumed by a building while ensuring a lighting function.

### CROSS-REFERENCE TO RELATED APPLICATIONS

This application claims priority under 35 U.S.C. §119 to Korean Patent Application No. 10-2013-0141118 filed on Nov. 20, 2013 in the Korean Intellectual Property Office, the disclosure of which is incorporated herein by reference in its entirety.

### TECHNICAL FIELD

The present disclosure relates to a solar cell structure for thermal insulation and a method for manufacturing the same.

### BACKGROUND

Recently, since existing energy resources such as coal and petroleum is predicted to become exhausted, the interest on alternative energy is increasing. Among them, a solar cell has the limelight as a next-generation battery for directly converting solar energy into electric energy by using a semiconductor device. However, the solar cell has problems in its production cost, energy conversion efficiency and life span. Therefore, the recent study on a solar cell is concentrated on the improvement of efficiency of the solar cell and relevant techniques.

In particular, as techniques using a solar cell are developed over various technical fields, products which apply solar cells to the exterior material of a building, for example a tile having a solar cell module, as disclosed in the related document, is being actively developed.

The exterior material of a building to which solar cells are applied requires thermal insulation performance and waterproofing property in order to decrease energy consumption of the building.

However, the exterior material of a building to which solar cells are applied is fabricated in a laminated glass form to produce electricity and ensure stability of construction resources, and such an exterior material however has low thermal insulation effect and bad lighting. In addition, moisture may penetrate into the solar cell module composed of glass plates, which deteriorates the performance of the solar cell module and lowers the power production.

### RELATED LITERATURES

### Patent Literature

Patent Literature 1: Korean Patent Registration No. 10-1315426

### SUMMARY

The present disclosure is directed to providing a solar cell structure for thermal insulation, which may have thermal insulation performance and waterproofing function for energy saving while having a lighting function.

The present disclosure is also directed to providing a method for manufacturing a solar cell structure for thermal insulation, which may have thermal insulation performance and waterproofing function for energy saving while having a lighting function.

In one aspect, there is provided a solar cell structure for thermal insulation, which includes: an intermediate support glass plate; a solar cell structure (A) provided at one side based on the support glass plate; and a vacuum glass panel structure (B) provided at the other side based on the support glass plate.

In the solar cell structure for thermal insulation according to an embodiment of the present disclosure, the solar cell structure (A) may include: an upper glass plate corresponding to the support glass plate; a solar cell array including a plurality of solar cells mounted to one surface of the support glass plate by means of an adhesive member, respectively; a second sealing unit surrounding the solar cell array and provided at a rim between the support glass plate and the upper glass plate; and a transparent filling unit for making the solar cell array be impregnated between the support glass plate and the upper glass plate.

In the solar cell structure for thermal insulation according to an embodiment of the present disclosure, the vacuum glass panel structure (B) may include: a lower glass plate corresponding to the support glass plate; a first sealing unit provided at a rim between the support glass plate and the lower glass plate; and a plurality of getter fillers provided between the support glass plate and the lower glass plate with a distance (d).

The solar cell structure for thermal insulation according to an embodiment of the present disclosure may further include at least one spacer for keeping a gap between the support glass plate and the upper glass plate, and the adhesive member may have a polygonal section by using an adhesive paste or a double-sided adhesive tape.

In the solar cell structure for thermal insulation according to an embodiment of the present disclosure, the second sealing unit may be provided to have a thickness greater than the sum of a thickness of the solar cell array and a thickness of the adhesive member, by using a double-sided adhesive tape or a glass frit.

In the solar cell structure for thermal insulation according to an embodiment of the present disclosure, the transparent filling unit may be made of a synthetic resin having a refractive index which is identical to a refractive index of the upper glass plate or similar thereto within a range of 1.5 to 2.0 thereof.

In the solar cell structure for thermal insulation according to an embodiment of the present disclosure, the first sealing unit may include a double-sided adhesive tape or a glass frit.

In the solar cell structure for thermal insulation according to an embodiment of the present disclosure, the getter filler may include any one of Ta, Cb, Zr, Th, Mg, Ba, Ti, Al, Nb, Fe, Li, Pd, Pt, Au, their compounds, and their oxides, as a gas-absorbing material.

In the solar cell structure for thermal insulation according to an embodiment of the present disclosure, the getter filler may include any one of calcium oxide, calcium chloride, zeolite, silica gel, alumina, activated carbon, and their mixtures, as a moisture-absorbing material.

In the solar cell structure for thermal insulation according to an embodiment of the present disclosure, the getter filler may have a polyhedral or cylindrical shape having a length of 0.4 to 1.0 mm and a height of 0.1 to 1.0 mm.

In another aspect, there is provided a method for manufacturing a solar cell structure for thermal insulation, which includes: (I) forming a vacuum glass panel structure (B) at the other side based on a support glass plate; and (II) forming a solar cell structure (A) at one side based on the support glass plate.

In the method for manufacturing a solar cell structure for thermal insulation according to an embodiment of the present disclosure, the operation (I) may include: (I-1) preparing the support glass plate and a lower glass plate; (I-2) loading a plurality of getter fillers on the upper surface of the lower glass plate; and (I-3) laminating the lower glass plate and the support glass plate by means of a first sealing unit provided at a rim of the lower glass plate.

In the method for manufacturing a solar cell structure for thermal insulation according to an embodiment of the present disclosure, the getter filler may include any one of Ta, Cb, Zr, Th, Mg, Ba, Ti, Al, Nb, Fe, Li, Pd, Pt, Au, their compounds, and their oxides, as a gas-absorbing material.

In the method for manufacturing a solar cell structure for thermal insulation according to an embodiment of the present disclosure, the getter filler may include any one of calcium oxide, calcium chloride, zeolite, silica gel, alumina, activated carbon, and their mixtures, as a moisture-absorbing material.

In the method for manufacturing a solar cell structure for thermal insulation according to an embodiment of the present disclosure, the getter filler may have a polyhedral or cylindrical shape having a length of 0.4 to 1.0 mm and a height of 0.1 to 1.0 mm.

In the method for manufacturing a solar cell structure for thermal insulation according to an embodiment of the present disclosure, the operation (II) may include: (II-1) providing a plurality of adhesive members to one surface of the support glass plate; (II-2) adhering solar cells of a solar cell array to the upper surface of each adhesive member; (II-3) sealing and adhering an upper glass plate corresponding to the support glass plate by using a second sealing unit provided along a rim of the support glass plate; and (II-4) forming a transparent filling unit between the support glass plate and the upper glass plate.

In the method for manufacturing a solar cell structure for thermal insulation according to an embodiment of the present disclosure, the operation (II-2) may further include adhering at least one spacer for keeping a gap between the support glass plate and the upper glass plate, and the adhesive member may have a polygonal section by using an adhesive paste or a double-sided adhesive tape.

In the method for manufacturing a solar cell structure for thermal insulation according to an embodiment of the present disclosure, in the operation the (II-3), the second sealing unit may be provided to have a thickness greater than the sum of a thickness of the solar cell array and a thickness of the adhesive member, by using a double-sided adhesive tape or a glass frit.

In the method for manufacturing a solar cell structure for thermal insulation according to an embodiment of the present disclosure, the operation (II-4) may include: (II-41) injecting a solution, obtained by melting a synthetic resin which has a refractive index identical to a refractive index of the upper glass plate or similar thereto within a range of 1.5 or 2.0 thereof, through a through hole at one side of the second sealing unit; (II-42) tilting a structure including the upper glass plate and the support glass plate in every direction during the injecting process; and (II-43) curing the solution, obtained by melting the synthetic resin, to form the transparent filling unit.

In the method for manufacturing a solar cell structure for thermal insulation according to an embodiment of the present disclosure, in the operation (II-41), air between the upper glass plate and the support glass plate may be exhausted through another through hole provided adjacent to the through hole at one side.

Features and advantages of the present disclosure will be apparent from the following detailed description taken in conjunction with the accompanying drawings.

Prior to the description, it should be understood that the terms used in the specification and the appended claims should not be construed as limited to general and dictionary meanings, but interpreted based on the meanings and concepts corresponding to technical aspects of the present disclosure on the basis of the principle that the inventor is allowed to define terms appropriately for the best explanation.

The solar cell structure for thermal insulation according to an embodiment of the present disclosure may have light transmission property, generate power by using solar rays, perform a thermal insulation material, have a lighting function, and save energy of a building.

The method for manufacturing a solar cell structure for thermal insulation according to an embodiment of the present disclosure may simultaneously form a solar cell structure provided at one side based on an intermediate support glass plate and a vacuum glass panel structure provided at the other side.

### BRIEF DESCRIPTION OF THE DRAWINGS

The above and other aspects, features and advantages of the disclosed exemplary embodiments will be more apparent from the following detailed description taken in conjunction with the accompanying drawings in which:

FIG. 1 is an exploded perspective view showing a solar cell structure for thermal insulation according to an embodiment of the present disclosure;

FIG. 2 is a cross-sectional view showing a solar cell structure for thermal insulation according to an embodiment of the present disclosure;

FIG. 3 is a rear view showing a solar cell structure for thermal insulation according to an embodiment of the present disclosure;

FIG. 4 is a cross-sectional view showing a solar cell structure for thermal insulation according to another embodiment of the present disclosure;

FIG. 5a is a perspective view showing a filler employed in the solar cell structure for thermal insulation according to an embodiment of the present disclosure;

FIG. 5b is a perspective view showing a filler employed in the solar cell structure for thermal insulation according to another embodiment of the present disclosure; and

FIGS. 6a to 6e are cross-sectional views for illustrating a method for manufacturing a solar cell structure for thermal insulation according to an embodiment of the present disclosure.

### DETAILED DESCRIPTION OF MAIN ELEMENTS

100: solar cell structure for thermal insulation
101: first sealing unit
102: second sealing unit
110: support glass plate
120: lower glass plate
122: getter filler
130: upper glass plate
140: solar cell
142: adhesive member
150: transparent filling unit
160: spacer
A: solar cell structure
B: vacuum glass panel structure

### DETAILED DESCRIPTION OF EMBODIMENTS

Objects, specific advantages and new features of the present disclosure will be more apparent from the following detailed description and embodiments taken in conjunction with the accompanying drawings. In the specification, when reference numerals are endowed to components in each drawing, it should be noted that like reference numerals denote like elements even though they are depicted in several drawings. In addition, the terms “first”, “second”, and the like are used for distinguishing one component from another, and components are not limited to the terms. Hereinafter, in a case where detailed description of known functions or configurations in relation to the present disclosure is judged as unnecessarily making the essence of the present disclosure vague, the detailed description will be excluded.

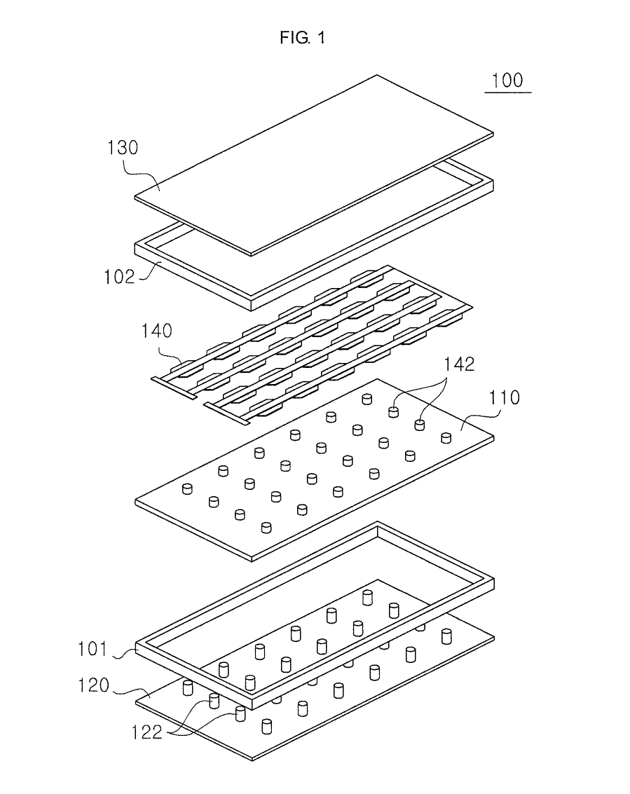

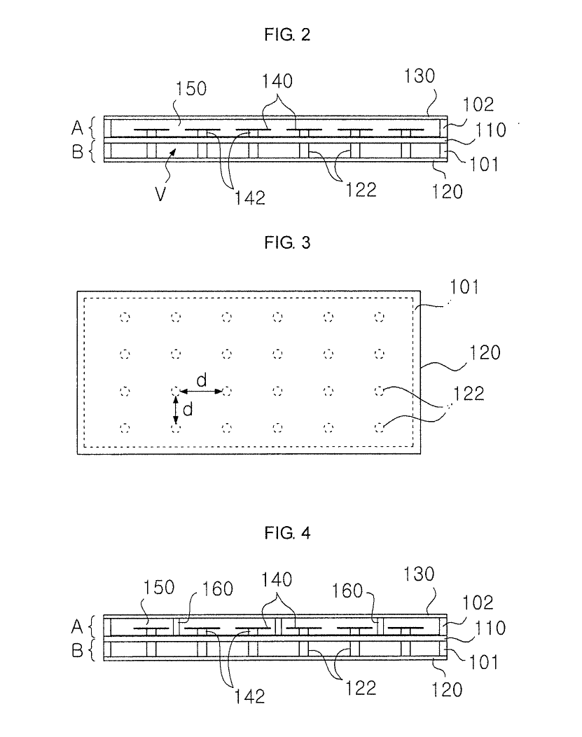

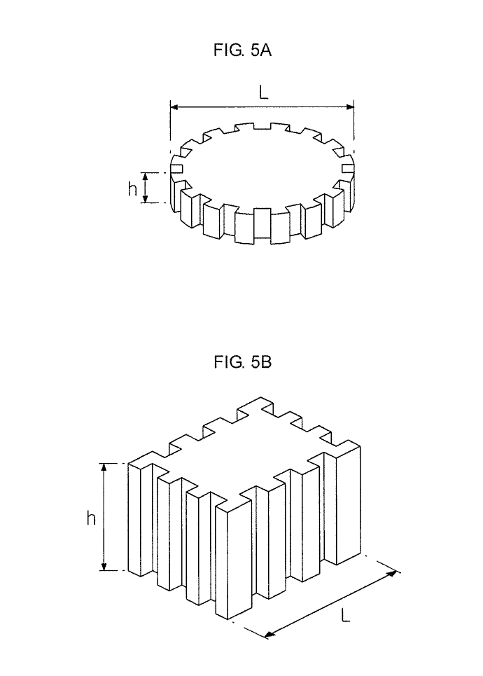

Hereinafter, preferred embodiments of the present disclosure will be described in detail with reference to the accompanying drawings. FIG. 1 is an exploded perspective view showing a solar cell structure for thermal insulation according to an embodiment of the present disclosure, FIG. 2 is a cross-sectional view showing a solar cell structure for thermal insulation according to an embodiment of the present disclosure, FIG. 3 is a rear view showing a solar cell structure for thermal insulation according to an embodiment of the present disclosure, FIG. 4 is a cross-sectional view showing a solar cell structure for thermal insulation according to another embodiment of the present disclosure, FIG. 5a is a perspective view showing a filler employed in the solar cell structure for thermal insulation according to an embodiment of the present disclosure, and FIG. 5b is a perspective view showing a filler employed in the solar cell structure for thermal insulation according to another embodiment of the present disclosure.

A solar cell structure 100 for thermal insulation according to an embodiment of the present disclosure includes a solar cell structure (A) provided at one side based on an intermediate support glass plate 110 and a vacuum glass panel structure (B) provided at the other side.

In detail, as shown in FIGS. 1 and 2, in the solar cell structure 100 for thermal insulation according to an embodiment of the present disclosure, the solar cell structure (A) includes a solar cell array having a plurality of solar cells 140 mounted to the upper surface of the support glass plate 110 by means of an adhesive member 142, respectively, a second sealing unit 102 surrounding the solar cell array and provided at a rim between the support glass plate 110 and the upper glass plate 130, and a transparent filling unit 150 injected between the support glass plate 110 and the upper glass plate 130 for making the solar cell array having the plurality of solar cells 140 to be impregnated.

The support glass plate 110 and the upper glass plate 130 have a plate shape and are spaced apart from each other to face in parallel with the same area, and particularly, they may be made of a tempered glass to protect the interior including the solar cell array from an external impact while allowing penetration of solar rays. For this, the support glass plate 110 and the upper glass plate 130 may be made of, for example, low-iron tempered glass which contains small iron.

The solar cell array includes a plurality of solar cells 140 mounted to the upper surface of the support glass plate 110 by means of the adhesive member 142, respectively, at least two ribbons for connecting the solar cells 140, and a bus ribbon for connecting the plurality of ribbons. Here, the solar cell 140 includes a solar cell made of silicon, and the adhesive member 142 may have, for example, an adhesive paste or a double-sided adhesive material in a circular shape or a polygonal shape such as a rectangular shape. The adhesive member 142 may be provided by forming a double-sided adhesive tape in a polygonal shape.

The adhesive member 142 may firmly support the solar cell array to prevent the solar cells 140 from being separated or deformed while a transparent resin is injected between the support glass plate 110 and the upper glass plate 130 to form the transparent filling unit 150, described later.

The second sealing unit 102 is adhered to the rim between the support glass plate 110 and the upper glass plate 130 by means of laminating to seal the support glass plate 110 and the upper glass plate 130 with a gap between them. For this, the second sealing unit 102 may be provided using, for example, a glass frit or a double-sided adhesive tape made of a synthetic resin with excellent transparency, impact absorbance, elasticity, tensile strength or the like, and may have a thickness greater than the sum of a thickness of the solar cell array and a thickness of the adhesive member 142.

In particular, the synthetic resin forming the second sealing unit 102 may include, for example, ethylene-vinyl acetate copolymer (EVA), poly vinyl butyral (PVB), ethylenevinyl acetate partial oxide, silicon resin, ester resin, olefin resin or the like.

The transparent filling unit 150 may be provided by injecting a synthetic resin, which has transparency and adhesion and is not discolored by light, in a molten state into the gap between the support glass plate 110 and the upper glass plate 130 so that the solar cell array is impregnated. The transparent filling unit 150 is adhered to the support glass plate 110 and the upper glass plate 130 to prevent penetration of external moisture and protect the solar cell array including the solar cells 140 from external impact (passivation), thereby improving the durability of the solar cell structure (A).

The transparent filling unit 150 having the above features may be made of a synthetic resin having a refractive index which is identical to a refractive index of the upper glass plate 130 or similar thereto within a range of 1.5 to 2.0 times thereof, for example a silicon resin, so that the light passing through the upper glass plate 130 is not reflected on the interface but penetrates.

Meanwhile, the vacuum glass panel structure (B) provided at the other side of the support glass plate 110 includes a lower glass plate 120 corresponding to the support glass plate 110, a first sealing unit 101 provided at a rim between the support glass plate 110 and the lower glass plate 120, and a plurality of getter fillers 122 provided between the support glass plate 110 and the lower glass plate 120 with a distance (d).

Similar to the upper glass plate 130, the lower glass plate 120 may have a plate shape, be spaced apart from the support glass plate 110 to face in parallel with the same area, and be made of, for example, low-iron tempered glass which contains small iron.

The first sealing unit 101 is adhered to the rim between the support glass plate 110 and the lower glass plate 120 by laminating to seal the support glass plate 110 and the lower glass plate 120 with a gap between them. The first sealing unit 101 may be formed with a double-sided adhesive tape or a glass frit, similar to the second sealing unit 102.

In particular, the first sealing unit 101 seals the support glass plate 110 and the lower glass plate 120 to provide an evacuated layer V in the gap between the support glass plate 110 and the lower glass plate 120.

The getter filler 122 is interposed in the evacuated layer V between the support glass plate 110 and the lower glass plate 120, thereby keeping the support glass plate 110 and the lower glass plate 120 to keep a predetermined gap between them together with the first sealing unit 101 and absorbing residual gas or moisture of the evacuated layer V. In particular, the getter filler 122 may absorb residual gas or moisture in the evacuated layer V to prevent, for example, dew condensation or increase of humidity.

At least one getter filler 122 may be provided in the evacuated layer V to form a matrix arrangement on a plane as shown in FIG. 3. Here, the distance (d) between the getter fillers 122 may be adjusted according to width, thickness or the like of the support glass plate 110 and the lower glass plate 120.

The arrangement of the getter fillers 122 is for a subsidiary purpose to maintain the gap of the evacuated layer V constantly, and the getter fillers 122 should be designed and arranged so that the stress around the getter fillers 122 generated by a vacuum pressure does not exceed a long-term allowable stress of glass material.

In addition, since the getter filler 122 may be made of a mixture material absorbing residual gas or moisture, the getter filler 12 may include any one of Ta, Cb, Zr, Th, Mg, Ba, Ti, Al, Nb, Fe, Li, Pd, Pt, Au, their compounds, and their oxides, as a gas-absorbing material.

The getter filler 122 having the above features may be formed with a cylindrical shape with an uneven side as shown in FIG. 5a or with a hexahedral shape with uneven sides as shown in FIG. 5b. Here, though not shown in the figures, the getter filler 122 is not limited to the cylindrical and hexahedral shapes but may have various shapes such as a cylindrical or hexahedral shape without an uneven side, an octahedral shape, a dodecahedral shape or the like.

The getter filler 122 having a cylindrical or hexahedral shape with an uneven side as described above may be formed with a length (L) of 0.4 to 1.0 mm and a height (h) of 0.1 to 1.0 mm, and may increase an area reacting with gas due to the uneven side, thereby improving the gas-absorbing effect.

If the getter filler 122 has a length (L) less than 0.4 mm, the load of the support glass plate 110 and the solar cell structure (A) may damage the getter filler 122 or excessively increase the stress around the getter filler 122. Meanwhile, if the getter filler 122 has a length (L) greater than 1.0 mm, the appearance may be deteriorated.

In addition, if the getter filler 122 has a height (h) less than 0.1 mm, it is difficult to prepare the evacuated layer V, and the support glass plate 110 and the lower glass plate 120 may contact each other.

Meanwhile, if the getter filler 122 has a height (h) greater than 1.0 mm, the aspect ratio of the getter filler 122 increases to deteriorate the shape stability, and thus the getter filler 122 may lay down when being loaded, which may be a factor deteriorating the durability of the vacuum glass panel structure (B). In other words, the gap between the support glass plate 110 and the lower glass plate 120 may increase too excessively, which is weak against an external impact or vibration.

Therefore, the gap between the support glass plate 110 and the lower glass plate 120 may be controlled by the height (h) of the getter filler 122.

Meanwhile, the distance between the getter fillers 122 may be adjusted according to the thicknesses of the support glass plate 110 and the lower glass plate 120 and may be about 10 to 30 mm.

The vacuum glass panel structure (B) configured as above may keep the evacuated layer V and improve the durability since the gas-absorbing effect is improved by the plurality of getter fillers 122 having a getter function.

Therefore, the solar cell structure for thermal insulation including the vacuum glass panel structure (B) having the getter fillers 122 therein according to an embodiment of the present disclosure prevent heat loss by conduction or convection by realizing insulation through the evacuated layer V.

Hereinafter, a solar cell structure for thermal insulation according to another embodiment of the present disclosure will be described with reference to FIG. 4. The solar cell structure for thermal insulation according to another embodiment of the present disclosure is different from the solar cell structure for thermal insulation according to the former embodiment of the present disclosure in the point that the solar cell structure (A) includes at least one spacer 160 for keeping a gap between the support glass plate 110 and the upper glass plate 130. Accordingly, any component or feature in relation to the solar cell structure for thermal insulation according to another embodiment of the present disclosure, which is substantially identical to that of the solar cell structure for thermal insulation according to the former embodiment of the present disclosure, will not be described again in detail.

In the solar cell structure for thermal insulation according to another embodiment of the present disclosure the present disclosure, the solar cell structure (A) includes at least one spacer 160 for keeping a gap between the support glass plate 110 and the upper glass plate 130, and the spacer 160 is provided between the solar cells 140 in at least one side between the support glass plate 110 and the upper glass plate 130.

At least one spacer 160 may be provided between the support glass plate 110 and the upper glass plate 130 at the center of the solar cell structure (A), or a plurality of spacers 160 may be provided to equal partitions of the solar cell structure (A) between the support glass plate 110 and the upper glass plate 130.

The spacer 160 may be formed with a tempered glass or a low-iron tempered glass, similar to that of the support glass plate 110 and the upper glass plate 130, or may be made of a transparent material by using the getter filler 122.

At this time, the spacer 160 may have a line shape, a pillar shape or a polygonal pillar shape, adhered between the support glass plate 110 and the upper glass plate 130 by an adhesive.

Accordingly, the solar cell structure for thermal insulation according to another embodiment of the present disclosure may implement the solar cell structure (A) to have a constant thickness by providing at least one spacer 160 to the solar cell structure (A). In particular, the spacer 160 made of the getter filler 122 may prevent external moisture from penetrating the solar cell structure (A), thereby improving the durability of the solar cell structure (A).

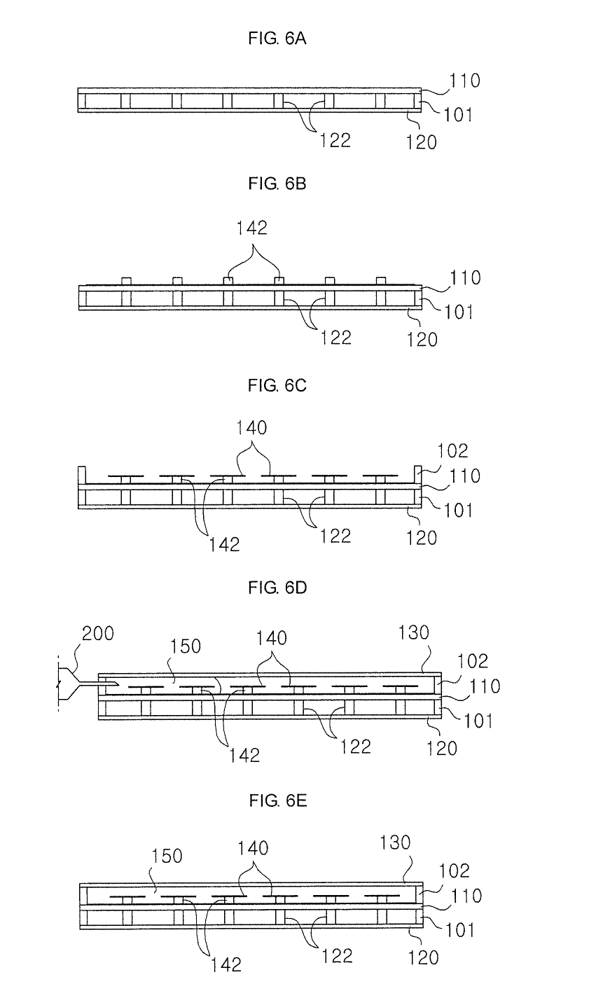

Hereinafter, a method for manufacturing a solar cell structure for thermal insulation according to an embodiment of the present disclosure will be described with reference to FIGS. 6a to 6e. FIGS. 6a to 6e are cross-sectional views for illustrating the method for manufacturing a solar cell structure for thermal insulation according to an embodiment of the present disclosure.

In the method for manufacturing a solar cell structure for thermal insulation according to an embodiment of the present disclosure, first, a vacuum glass panel structure (B) is formed at the other side based on the support glass plate 110, as shown in FIG. 6a.

In detail, in order to form the vacuum glass panel structure (B), a support glass plate 110 and a lower glass plate 120 are prepared in a vacuum chamber, a plurality of getter fillers 122 is loaded on the upper surface of the lower glass plate 120, and a first sealing unit 101 is provided along a rim of the lower glass plate 120.

Here, the getter fillers 122 may be loaded on the upper surface of the lower glass plate 120 in a matrix arrangement with a distance (d) adjusted according to width, thickness or the like of the support glass plate 110 and the lower glass plate 120.

After the plurality of getter fillers 122 is loaded, the first sealing unit 101 formed with a double-sided adhesive tape or a glass frit is provided along the rim of the lower glass plate 120, and the support glass plate 110 is adhered corresponding to the lower glass plate 120 by means of the first sealing unit 101 by lamination.

At this time, after the lamination is performed, the first sealing unit 101 is formed to have the same thickness as the getter filler 122, and the plurality of getter fillers 122 is adhered between the support glass plate 110 and the lower glass plate 120.

Here, even though the process for forming the vacuum glass panel structure (B) is performed in a vacuum chamber, the present disclosure is not limited thereto, and it is also possible that the plurality of getter fillers 122 is interposed between the support glass plate 110 and the lower glass plate 120 at a normal temperature and an atmospheric pressure and adhered by means of the first sealing unit 101, and then the evacuated layer V is formed by sucking air through a suction hole formed at one side of the support glass plate 110 or the lower glass plate 120.

After the vacuum glass panel structure (B) is formed, as shown in FIG. 6b, an adhesive member 142 is provided at one surface of the support glass plate 110 to form the solar cell structure (A).

Here, the adhesive member 142 may be formed with an adhesive paste or a double-sided adhesive tape in a circular shape or a polygonal shape such as a rectangular shape, and the adhesive member 142 may be prepared by forming a double-sided adhesive tape with a polygonal section.

The adhesive member 142 may firmly support the solar cell array while a transparent resin is injected between the support glass plate 110 and the upper glass plate 130 to form the transparent filling unit 150, described later, thereby preventing the solar cells 140 from being separated or deformed.

With respect to the adhesive member 142 prepared as above, as shown in FIG. 6c, the solar cells 140 of the solar cell array are adhered to the upper surface of the adhesive member 142, and a second sealing unit 102 is provided along the rim of one surface of the support glass plate 110.

In detail, the second sealing unit 102 may be provided using, for example, a glass frit or a double-sided adhesive tape made of a synthetic resin with excellent transparency, impact absorbance, elasticity, tensile strength or the like, and may have a thickness greater than the sum of a thickness of the solar cell array and a thickness of the adhesive member 142.

In particular, the synthetic resin forming the second sealing unit 102 may include, for example, ethylene-vinyl acetate copolymer (EVA), poly vinyl butyral (PVB), ethylenevinyl acetate partial oxide, silicon resin, ester resin, olefin resin or the like.

By using the second sealing unit 102, as shown in FIG. 6d, the upper glass plate 130 is adhered corresponding to the support glass plate 110, and the second sealing unit 102 is cured.

At this time, selectively, at least one spacer 160 shown in FIG. 4 may be provided between the solar cells 140 in at least one side between the support glass plate 110 and the upper glass plate 130 and adhere the upper glass plate 130 and the support glass plate 110 correspondingly.

Accordingly, in a state where the solar cell array and the adhesive member 142 are interposed between the support glass plate 110 and the upper glass plate 130 and sealed by the second sealing unit 102, as shown in FIG. 6d, a solution obtained by melting a synthetic resin is injected through a through hole at one side of the second sealing unit 102 by using an injecting machine 200 in order to form the transparent filling unit 150. Here, the synthetic resin forming the transparent filling unit 150 includes a synthetic resin having a refractive index which is identical to a refractive index of the upper glass plate 130 or similar thereto within a range of 1.5 to 2.0 times thereof, for example a silicon resin, so that the light passing through the upper glass plate 130 is not reflected on the interface but penetrates.

At this time, for helping the injection of the solution obtained by melting a synthetic resin, another through hole may be formed at a position adjacent to the through hole at one side of the second sealing unit 102 through which the injecting machine 200 moves, so that the air between the support glass plate 110 and the upper glass plate 130 is exhausted during the injecting process.

In addition, the process of injecting the solution for forming the transparent filling unit 150 through the through hole at one side of the second sealing unit 102 may be performed while tilting a structure from the lower glass plate 120 to the upper glass plate 130 in every direction.

Accordingly, it is possible to prevent bubbles from being generated at the transparent filling unit 150, which is charged between the support glass plate 110 and the upper glass plate 130, during the injecting process.

After filling the solution for forming the transparent filling unit 150, if the through hole at one side of the second sealing unit 102 and another through hole are closed for sealing and also the transparent filling unit 150 charged between the support glass plate 110 and the upper glass plate 130 is cured, as shown in FIG. 6e, the solar cell array is impregnated with the transparent filling unit 150 between the support glass plate 110 and the upper glass plate 130.

The transparent filling unit 150 prevents penetration of external moisture and protects the solar cell array including the solar cells 140 from external impact, thereby improving the durability of the solar cell structure (A).

The method for manufacturing a solar cell structure for thermal insulation according to an embodiment of the present disclosure as described above forms the solar cell structure (A) at one side based on the intermediate support glass plate 110 and the vacuum glass panel structure (B) at the other side, thereby generating power through solar cell structure (A) and simultaneously forming an insulation structure by the vacuum glass panel structure (B) to prevent heat loss by conduction or convection.

The solar cell structure 100 for thermal insulation according to an embodiment of the present disclosure, manufactured as above, may be used as an exterior material of a building with light transparency to have an insulation function while generating power by using solar ray, thereby saving the energy consumed by the building while ensuring a lighting function.

While the present invention has been described in detail with respect to the embodiments, this is just for illustrating the present disclosure in detail, and the present disclosure is not limited thereto.

In addition, it will be apparent to those skilled in the art that various changes and modifications can be made without departing from the spirit and scope of the present disclosure.

What is claimed is:

1. A solar cell structure for thermal insulation, comprising:
an intermediate support glass plate;
a solar cell structure (A) provided at one side based on the support glass plate; and
a vacuum glass panel structure (B) provided at the other side based on the support glass plate.

2. The solar cell structure for thermal insulation according to claim 1, wherein the solar cell structure (A) includes:
an upper glass plate corresponding to the support glass plate;
a solar cell array including a plurality of solar cells mounted to one surface of the support glass plate by means of an adhesive member, respectively;
a second sealing unit surrounding the solar cell array and provided at a rim between the support glass plate and the upper glass plate; and
a transparent filling unit for making the solar cell array be impregnated between the support glass plate and the upper glass plate.

3. The solar cell structure for thermal insulation according to claim 1, wherein the vacuum glass panel structure (B) includes:
a lower glass plate corresponding to the support glass plate;
a first sealing unit provided at a rim between the support glass plate and the lower glass plate; and
a plurality of getter fillers provided between the support glass plate and the lower glass plate with a distance (d).

4. The solar cell structure for thermal insulation according to claim 2, further comprising at least one spacer for keeping a gap between the support glass plate and the upper glass plate,
wherein the adhesive member has a polygonal section by using an adhesive paste or a double-sided adhesive tape.

5. The solar cell structure for thermal insulation according to claim 2,
wherein the second sealing unit is provided to have a thickness greater than the sum of a thickness of the solar cell array and a thickness of the adhesive member, by using a double-sided adhesive tape or a glass frit.

6. The solar cell structure for thermal insulation according to claim 2,
wherein the transparent filling unit is made of a synthetic resin having a refractive index which is identical to a refractive index of the upper glass plate or similar thereto within a range of 1.5 to 2.0 thereof.

7. The solar cell structure for thermal insulation according to claim 3,
wherein the first sealing unit includes a double-sided adhesive tape or a glass frit.

8. The solar cell structure for thermal insulation according to claim 3,
wherein the getter filler includes any one of Ta, Cb, Zr, Th, Mg, Ba, Ti, Al, Nb, Fe, Li, Pd, Pt, Au, their compounds, and their oxides, as a gas-absorbing material.

9. The solar cell structure for thermal insulation according to claim 3,
wherein the getter filler includes any one of calcium oxide, calcium chloride, zeolite, silica gel, alumina, activated carbon, and their mixtures, as a moisture-absorbing material.

10. The solar cell structure for thermal insulation according to claim 3,
wherein the getter filler has a polyhedral or cylindrical shape having a length of 0.4 to 1.0 mm and a height of 0.1 to 1.0 mm.

11. A method for manufacturing a solar cell structure for thermal insulation, comprising:
(I) forming a vacuum glass panel structure (B) at the other side based on a support glass plate; and
(II) forming a solar cell structure (A) at one side based on the support glass plate.

12. The method for manufacturing a solar cell structure for thermal insulation according to claim 11, wherein said operation (I) includes:
(I-1) preparing the support glass plate and a lower glass plate;
(I-2) loading a plurality of getter fillers on the upper surface of the lower glass plate; and
(I-3) laminating the lower glass plate and the support glass plate by means of a first sealing unit provided at a rim of the lower glass plate.

13. The method for manufacturing a solar cell structure for thermal insulation according to claim 12,
wherein the getter filler includes any one of Ta, Cb, Zr, Th, Mg, Ba, Ti, Al, Nb, Fe, Li, Pd, Pt, Au, their compounds, and their oxides, as a gas-absorbing material.

14. The method for manufacturing a solar cell structure for thermal insulation according to claim 12,
wherein the getter filler includes any one of calcium oxide, calcium chloride, zeolite, silica gel, alumina, activated carbon, and their mixtures, as a moisture-absorbing material.

15. The method for manufacturing a solar cell structure for thermal insulation according to claim 12,
wherein the getter filler has a polyhedral or cylindrical shape having a length of 0.4 to 1.0 mm and a height of 0.1 to 1.0 mm.

16. The method for manufacturing a solar cell structure for thermal insulation according to claim 11, wherein said operation (II) includes:
(II-1) providing a plurality of adhesive members to one surface of the support glass plate;
(II-2) adhering solar cells of a solar cell array to the upper surface of each adhesive member;
(II-3) sealing and adhering an upper glass plate corresponding to the support glass plate by using a second sealing unit provided along a rim of the support glass plate; and
(II-4) forming a transparent filling unit between the support glass plate and the upper glass plate.

17. The method for manufacturing a solar cell structure for thermal insulation according to claim 16, wherein said operation (II-2) further includes:
adhering at least one spacer for keeping a gap between the support glass plate and the upper glass plate,
wherein the adhesive member has a polygonal section by using an adhesive paste or a double-sided adhesive tape.

18. The method for manufacturing a solar cell structure for thermal insulation according to claim 16,
wherein in said operation the (II-3), the second sealing unit is provided to have a thickness greater than the sum of a thickness of the solar cell array and a thickness of the adhesive member, by using a double-sided adhesive tape or a glass frit.

19. The method for manufacturing a solar cell structure for thermal insulation according to claim 16, wherein said operation (II-4) includes:
(II-41) injecting a solution, obtained by melting a synthetic resin which has a refractive index identical to a refractive index of the upper glass plate or similar thereto within a range of 1.5 to 2.0 thereof, through a through hole at one side of the second sealing unit;
(II-42) tilting a structure including the upper glass plate and the support glass plate in every direction during the injecting process; and
(II-43) curing the solution, obtained by melting the synthetic resin, to form the transparent filling unit.

20. The method for manufacturing a solar cell structure for thermal insulation according to claim 19,
wherein in said operation (II-41), air between the upper glass plate and the support glass plate is exhausted through another through hole provided adjacent to the through hole at one side.
